(19) United States
(12) Patent Application Publication
(10) Pub. No.: US 2020/0043725 A1
(43) Pub. Date: Feb. 6, 2020

(54) METHOD FOR MANUFACTURING A SILICON CARBIDE EPITAXIAL SUBSTRATE

(71) Applicant: SUMITOMO ELECTRIC INDUSTRIES, LTD., Osaka (JP)

(72) Inventor: Keiji WADA, Hyogo (JP)

(21) Appl. No.: 16/338,795

(22) PCT Filed: Jun. 8, 2017
(86) PCT No.: PCT/JP2017/021354

§ 371 Date: Apr. 2, 2019

(30) Foreign Application Priority Data
Oct. 28, 2016 (JP) 2016-212201

(51) Int. Cl. H01L 21/02; C30B 25/14; C23C 16/32; C30B 29/36

(52) U.S. Cl. CPC H01L 21/02378; C30B 25/14; C23C 16/325; C30B 29/36; H01L 21/02529; H01L 21/02433; H01L 21/0262

(57) ABSTRACT

A method for manufacturing a silicon carbide epitaxial substrate includes a process of loading a plurality of silicon carbide single crystal substrates on a substrate holder, and a process of depositing a silicon carbide epitaxial layer on the plurality of silicon carbide single crystal substrates at the same time by rotating the substrate holder about an axis perpendicular to a principal surface of the silicon carbide single crystal substrates while supplying a gas containing carbon, a gas containing silicon, nitrogen gas and ammonia gas. A flow rate of the ammonia gas to a flow rate of the nitrogen gas is not more than 0.0089.

### TECHNICAL FIELD

The present disclosure relates to a method for manufacturing a silicon carbide epitaxial substrate.

The present application is based on and claims priority to Japanese Patent Application No. 2016-212201 filed on Oct. 28, 2016, the entire contents of which are herein incorporated by reference.

### BACKGROUND ART

A silicon carbide epitaxial substrate is manufactured by preparing a silicon carbide single crystal substrate, and depositing a silicon carbide epitaxial layer containing doped impurities, on the silicon carbide single crystal substrate by epitaxial growth (for example, see Patent Document 1).

### Patent Document 1: Japanese Laid-Open Patent Application Publication No. 2014-170891

### SUMMARY OF THE INVENTION

A method for manufacturing a silicon carbide epitaxial substrate according to an aspect of the present disclosure includes a process of loading a plurality of silicon carbide single crystal substrates on a substrate holder, and a process of depositing a silicon carbide epitaxial layer on the plurality of silicon carbide single crystal substrates at the same time by rotating the substrate holder about an axis perpendicular to a principal surface of the silicon carbide single crystal substrates while supplying a gas containing carbon, a gas containing silicon, nitrogen gas and ammonia gas. A flow rate of the ammonia gas to a flow rate of the nitrogen gas is not more than 0.0089.

### BRIEF DESCRIPTION OF THE DRAWINGS

FIG. 1 is a partial cross-sectional view schematically illustrating a silicon carbide epitaxial substrate;

FIG. 2 is a schematic cross-sectional view illustrating an example of a configuration of a film deposition apparatus used in a method for manufacturing a silicon carbide epitaxial substrate according to a first embodiment;

FIG. 3 is a schematic top view illustrating the inside of a chamber of a film deposition apparatus used in a method for manufacturing a silicon carbide epitaxial substrate according to a first embodiment;

FIG. 4 is an explanatory diagram of a measurement of a carrier concentration of a silicon carbide epitaxial layer of a silicon carbide epitaxial substrate;

FIG. 5 is a relationship diagram between a measurement position of a silicon carbide epitaxial layer deposited by supplying nitrogen gas, and a carrier concentration of the silicon carbide epitaxial layer;

FIG. 6 is a relationship diagram between a measurement position of a silicon carbide epitaxial layer deposited by supplying ammonia gas, and a carrier concentration of the silicon carbide epitaxial layer;

FIG. 7 is a relationship diagram between a measurement position of a silicon carbide epitaxial layer deposited by supplying a mixed gas of nitrogen gas and ammonia gas, and a carrier concentration of the silicon carbide epitaxial layer;

FIG. 8 is a relationship diagram between a proportion of a nitrogen based gas and a width of concentration distribution of a carrier concentration of a silicon carbide epitaxial layer;

FIG. 9 is a relationship diagram between a supplied nitrogen gas or ammonia gas, and a carrier concentration of a silicon carbide epitaxial layer;

FIG. 10 is a flowchart illustrating an outline of a method for manufacturing a silicon carbide epitaxial substrate in a first embodiment;

FIG. 11 is a timing chart illustrating an example of temperature control and gas flow rate control in a film deposition apparatus in a first embodiment;

FIG. 12 is a relationship diagram between a measurement position of a silicon carbide epitaxial layer deposited by revolving and rotating a silicon carbide single crystal substrate while supplying a mixed gas of nitrogen gas and ammonia gas and a carrier concentration of the silicon carbide epitaxial layer; and

FIG. 13 is a schematic top view illustrating the inside of a film deposition apparatus used in a method for manufacturing a silicon carbide epitaxial substrate in a second embodiment.

### MODE OF CARRYING OUT THE INVENTION

### Problems to be Solved by the Present Disclosure

A silicon carbide epitaxial substrate requires not only uniformity of a film thickness of a silicon carbide epitaxial layer across the entire surface of the substrate but also uniformity of concentration distribution of doped impurities. When the concentration distribution of the impurities varies, characteristics of a semiconductor device manufactured by using the silicon carbide epitaxial substrate such as on-resistance vary and become non-uniform, which is unfavorable.

Hence, a method for manufacturing a silicon carbide epitaxial substrate that makes the concentration distribution of the doped impurities uniform across the entire surface of the silicon carbide epitaxial layer is demanded.

One of the purposes of the present disclosure is to provide a method for manufacturing a silicon carbide epitaxial substrate capable of improving uniformity of concentration distribution of impurities doped into a silicon carbide epitaxial layer across a surface of the substrate.

Embodiments to carry out the technology of the present disclosure are described below. Same numerals are attached to the same components, and an overlapping description is omitted.

### Description of Embodiments of the Present Disclosure

To begin with, embodiments of the present disclosure are listed and described below. It should be noted that in the below-mentioned figures, the same or corresponding locations are given the same reference characters and are not described repeatedly. Regarding crystallographic indications in the present specification, an individual orientation is represented by [ ], a group orientation is represented by < >, and an individual plane is represented by ( ) and a group plane is represented by { }. In addition, a negative index is supposed to be crystallographically indicated by putting “-” (bar) above a numeral, but is indicated by putting the negative sign before the numeral in the present specification.

[1] A method for manufacturing a silicon carbide epitaxial substrate according to an embodiment of the present disclosure includes a process of loading a plurality of silicon carbide single crystal substrates on a substrate holder, and a process of depositing a silicon carbide epitaxial layer on the plurality of silicon carbide single crystal substrates at the same time by rotating the substrate holder about an axis perpendicular to a principal surface of the silicon carbide single crystal substrates while supplying a gas containing carbon, a gas containing silicon, nitrogen gas and ammonia gas, wherein a flow rate of the ammonia gas to a flow rate of the nitrogen gas is not more than 0.0089.

The inventor of the present application found that concentration distribution of a carrier concentration in a silicon carbide epitaxial layer differs between supplied nitrogen gas and ammonia gas in depositing the silicon carbide epitaxial layer. Specifically, as described later, the inventor found that the concentration distribution of the carrier concentration differs between supplied nitrogen gas and ammonia gas when placing a plurality of silicon carbide single crystal substrates on a substrate holder and rotating (revolution) the substrate holder. When further performing examination, the inventor found that uniformity of the concentration distribution of the carrier concentration improves by setting a flow rate of ammonia gas to a flow rate of nitrogen gas at not more than 0.0089 when supplying both nitrogen gas and ammonia gas.

Accordingly, the uniformity of the concentration distribution of the carrier concentration can be improved by revolving the plurality of silicon carbide single crystal substrates while supplying nitrogen gas and ammonia gas such that the flow rate of ammonia gas to the flow rate of nitrogen gas becomes not more than 0.0089, and depositing the silicon carbide epitaxial layer.

[2] A method for manufacturing a silicon carbide epitaxial substrate according to an embodiment of the present disclosure includes a process of loading a plurality of silicon carbide single crystal substrates on a substrate holder, and a process of depositing a silicon carbide epitaxial layer on the plurality of silicon carbide single crystal substrates at the same time by rotating the substrate holder about an axis perpendicular to a principal surface of the silicon carbide single crystal substrates and rotating each of the silicon carbide single crystal substrates about an axis perpendicular to a principal surface of each of the silicon carbide single crystal substrates while supplying a gas containing carbon, a gas containing silicon, and ammonia gas.

Moreover, the inventor found that the concentration distribution of the carrier concentration can be further improved by rotating and revolving the silicon carbide single crystal substrates while supplying ammonia gas or a mixed gas of nitrogen gas and ammonia gas, and depositing the silicon carbide epitaxial layer.

Accordingly, the uniformity of the concentration distribution of the carrier concentration can be improved by rotating and revolving the plurality of silicon carbide substrates while supplying ammonia gas or a mixed gas of nitrogen gas and ammonia gas, and depositing the silicon carbide epitaxial layer.

[3] In the step of depositing the silicon carbide epitaxial layer, nitrogen gas is also supplied, and a flow rate of the ammonia gas to the flow rate of the nitrogen gas is not more than 0.0089.

[4] A method for manufacturing a silicon carbide epitaxial substrate according to an embodiment of the present disclosure includes a process of depositing a silicon carbide epitaxial layer on the silicon carbide single crystal substrate by supplying a gas containing carbon, a gas containing silicon, nitrogen gas and ammonia gas, wherein a flow rate of the ammonia gas to a flow rate of the nitrogen gas is not more than 0.0089.

[5] The gas containing the carbon is propane, and the gas containing the silicon is silane.

[6] A diameter of the silicon carbide single crystal substrate is not less than 100 mm.

[7] The silicon carbide epitaxial layer is formed by film deposition by a CVD method.

### Details of Embodiments of the Present Invention

Although one embodiment of the present disclosure (which is expressed as “the present embodiment” hereinafter) is described below in detail, the present disclosure is not limited to these.

### First Embodiment

[Silicon Carbide Epitaxial Substrate]

A silicon carbide epitaxial substrate 100 in the present embodiment is described below.

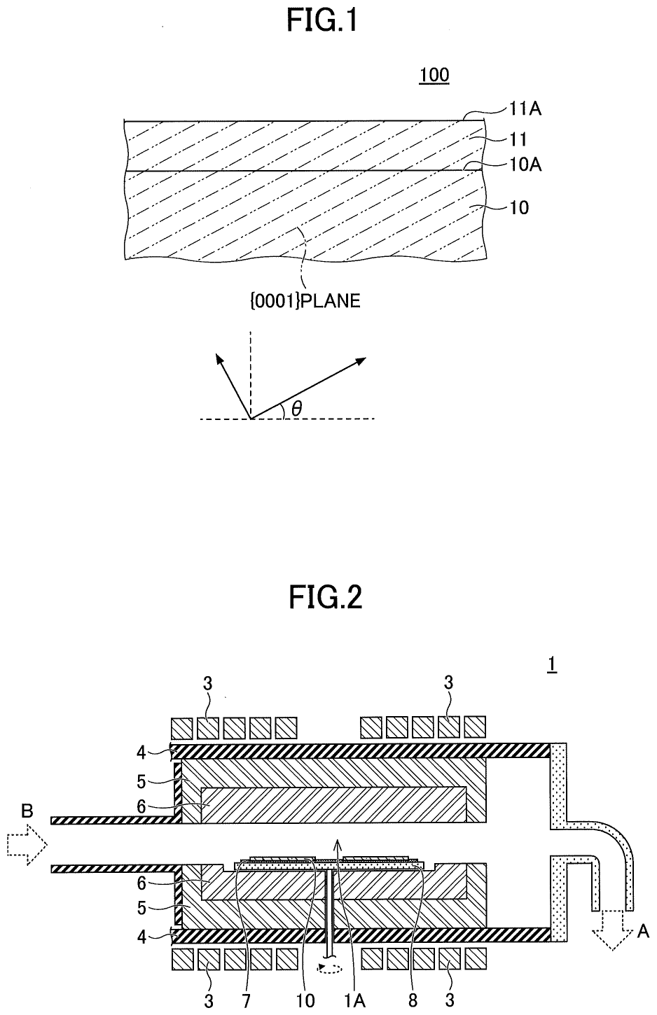

FIG. 1 is a cross-sectional view illustrating an example of a structure of a silicon carbide epitaxial substrate 100 in the present embodiment. The silicon carbide epitaxial substrate 100 in the present embodiment includes a silicon carbide single crystal substrate 10 having a principal surface 10A inclined at an off angle θ from a predeteLinined crystal plane, and a silicon carbide epitaxial layer 11 formed on the principal surface 10A of the silicon carbide single crystal substrate 10. The predetermined crystal plane is preferably a (0001) plane or a (000-1) plane.

The silicon carbide single crystal substrate 10 is made of, for example, a hexagonal silicon carbide of a 4H polytype. The silicon carbide single crystal substrate 10 contains an impurity element such as nitrogen (N), and a conductivity type of the silicon carbide single crystal substrate 10 is an n-type. The concentration of impurities such as nitrogen (N) contained in the silicon carbide single crystal substrate 10 is, for example, not less than 1*10¹⁸ cm⁻³ and not more than 1*10¹⁹ cm⁻³.

The silicon carbide epitaxial layer 11 is formed in contact with the principal surface 10A of the silicon carbide single crystal substrate 10. The thickness of the silicon carbide epitaxial layer 11 is, for example, not less than 5 μm and not more than 40 μm, and a top surface of the silicon carbide epitaxial layer 11 becomes a surface 11A. The silicon carbide epitaxial layer 11 contains impurities such as nitrogen (N), and the conductivity type of the silicon carbide epitaxial layer 11 is an n-type. The impurity concentration that is a carrier concentration of the silicon carbide epitaxial layer 11 may be lower than the impurity concentration of the silicon carbide single crystal substrate 10. The impurity concentration of the silicon carbide epitaxial layer 11 is, for example, not less than 1*10¹⁴ cm⁻³ and not more than 1*10¹⁶ cm⁻³.

[Film Deposition Apparatus]

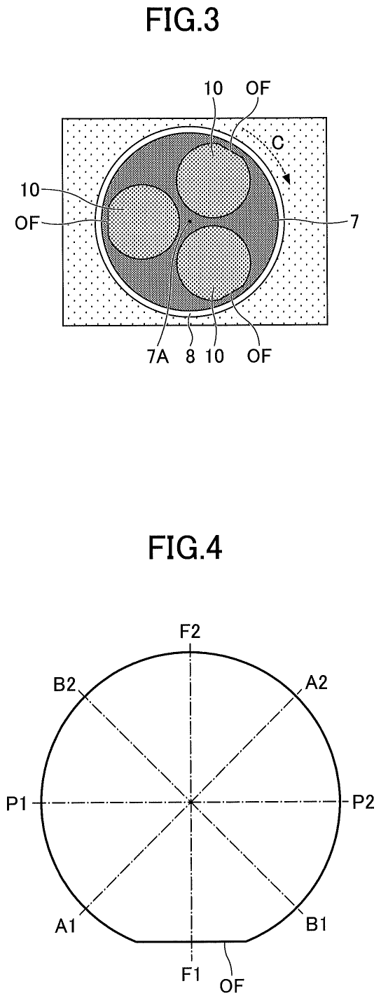

Next, a film deposition apparatus for manufacturing a silicon carbide epitaxial substrate according to the present embodiment is described below with reference to FIG. 2 and FIG. 3. FIG. 2 is a schematic cross-sectional view illustrating an example of a configuration of the film deposition apparatus used in the present embodiment. FIG. 3 is a top view of the inside of a chamber of this film deposition apparatus as seen from above. The film deposition apparatus 1 illustrated in FIG. 2 and FIG. 3 is a lateral type hot wall CVD (Chemical Vapor Deposition) apparatus. As illustrated in FIG. 2, the film deposition apparatus 1 includes a heating element 6, a heat insulator 5, a quartz tube 4, and an induction heating coil 3. The heating element 6 is made of, for example, carbon. As illustrated in FIG. 2, the film deposition apparatus 1 includes the heating element 6 having an angular cross-sectional tubular shape formed integrally, and two flat parts are formed to face each other inside the heating element 6 having the angular cross-sectional tubular shape. A space surrounded by the two flat parts forms a chamber 1A. The chamber 1A is referred to as a “gas flow channel.” As illustrated in FIG. 3, a substrate holder 7 on which a plurality of, for example, three silicon carbide single crystal substrates 10 can be placed, is installed on a rotary susceptor 8 in a chamber 1A.

The heat insulator 5 is arranged so as to surround an outer circumference of the heating element 6. The chamber 1A is insulated from the outside of the film deposition apparatus 1 by the heat insulator 5. The quartz tube 4 is arranged so as to surround the outer circumference of the heat insulator 5. The induction heating coil 3 is arranged so as to wind around the outer circumference of the heat insulator 5. The film deposition apparatus 1 is configured to be able to control the temperature in the chamber 1A by supplying an alternate current to the induction heating coil 3 to cause the heating element 6 to be inductively heated. On this occasion, the quartz tube 4 is hardly heated because the heat insulator 5 insulates heat.

In the film deposition apparatus 1 illustrated in FIG. 2, the chamber 1A is evacuated in a direction illustrated by a broken arrow A. Moreover, when a silicon carbide epitaxial layer 11 is deposited, a gas containing a carbon component that becomes a source gas, a gas containing a silicon component, ammonia (NH₃) gas, nitrogen gas (N₂), and hydrogen (H₂) gas as a carrier gas are supplied in a direction illustrated by a broken arrow B. In the present embodiment, propane (C₃H₈) gas and the like are used as a gas containing a carbon component, and a silane gas and the like are used as a gas containing a silicon component.

When the silicon carbide epitaxial layer 11 is deposited, the rotary susceptor 8 is rotated so as to rotate about a rotational axis 7A of the substrate holder 7. Thus, the silicon carbide single crystal substrates 10 placed on the substrate holder 7 can be revolved. Here, in the present embodiment, the substrate holder 7 is rotated by rotating the rotary susceptor 8 about the axis perpendicular to the principal surfaces 10A of the silicon carbide single crystal substrates 10. The rotational speed of the rotary susceptor 8 is, for example, not less than 10 RPM and not more than 100 RPM. Hence, the film deposition apparatus 1 can deposit the silicon carbide epitaxial layer 11 on a plurality of, for example, three silicon carbide single crystal substrates 10 at the same time. Here, the rotation of the substrate holder 7 is performed by, for example, a gas flow method.

[Gas Containing Impurity Element]

A gas containing an impurity element used to dope the impurity element into the silicon carbide epitaxial layer 11 in the silicon carbide epitaxial substrate is described below. Nitrogen (N) is doped to make the silicon carbide epitaxial layer 11 an n-type, and ammonia and nitrogen are cited as gases to dope nitrogen (N). Therefore, the inventors of the present application conducted an experiment for depositing the silicon carbide epitaxial layer 11 by placing three silicon carbide single crystal substrates 10 having six inches on the substrate holder 7 and rotating the substrate holder 7 about the rotational axis 7A in the film deposition apparatus illustrated in FIG. 2. Each of the silicon carbide single crystal substrates 10 is loaded so that an orientation flat (orientation flat) (which may be referred to as an ori-fla, OF or the like) is arranged at the outer edge side of the substrate holder 7.

The silicon carbide epitaxial layer 11 was formed by performing film deposition while supplying propane gas at 63 sccm, a silane gas at 140 sccm, and a gas to dope an impurity element at a temperature of 1640° C. in the process chamber 1A.

As the gas containing the impurity element to dope the impurity element, a sample SE1 deposited by supplying nitrogen gas and a sample SE2 deposited by supplying ammonia gas were produced, and concentration distribution of the carrier concentration of these was examined. The concentration distribution of the carrier concentration was examined using CVmap 92A, which is a mercury CV device made by Four Dimensions, Inc. The measurement was performed by applying an application voltage from about zero to about −5 V to measure voltage dependency of a depletion layer capacitance C of an epitaxial layer.

As illustrated at FIG. 4, the concentration distribution is a result of measuring the carrier concentrations at positions of total 41 points of the center of the silicon carbide epitaxial substrate, respective ten points in a direction indicated by dashed and dotted lines F1-F2, P1-P2, A1-A2, and B1-B2. The dashed and dotted line F1-F2 is a line connecting the center of an ori-fla (OF) and a position opposite to the center of the ori-fla (OF), and is a line passing through the center of the silicon carbide epitaxial substrate. The dashed and dotted line P1-P2 is a line that crosses the dashed and dotted line F1-F2 perpendicularly thereto at the center of the silicon carbide epitaxial substrate. The dashed and dotted line A1-A2 is a line that makes an angle of 45° with the respective dashed and dotted line A1-A2 and the dashed and dotted line P1-P2 at the center of the silicon carbide epitaxial substrate. The dashed and dotted line B1-B2 is a line that crosses the dashed and dotted line A1-A2 perpendicularly thereto at the center of the silicon carbide epitaxial substrate.

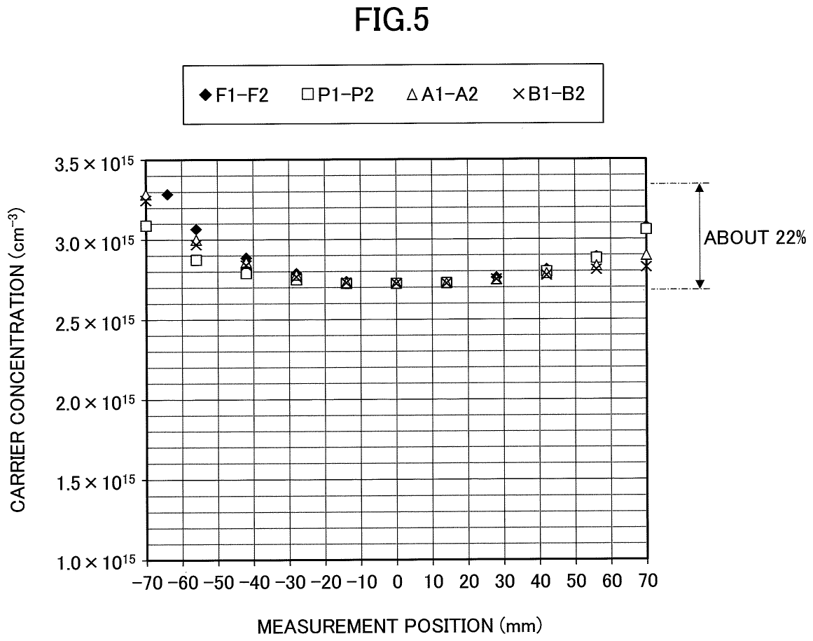

FIG. 5 shows a concentration distribution of a carrier concentration in the sample SE1 deposited by supplying nitrogen gas at 11 sccm as the gas to dope the impurity element. As shown in FIG. 5, when a film is deposited by supplying nitrogen gas, the carrier concentration in the silicon carbide epitaxial layer is likely to be low at a center location and to be high at peripheral locations. As a result, the width of the concentration distribution of the carrier concentration in the sample SE1 was about 22%. Here, the width of the concentration distribution of the carrier concentration is calculated from the maximum value of the carrier concentration, the minimum value of the carrier concentration, and the average value of the carrier concentration at the 41 measurement positions by using a formula shown in the following formula 1.

$$[ Formula 1 ]$$

$$\begin{matrix}WIDTH OF \\ CONCENTRATION \\ DISTRIBUTION\end{matrix} = \frac{( \begin{matrix}MAXIMUM VALUE \\ OF CARRIER \\ CONCENTRATION\end{matrix} ) - ( \begin{matrix}MINIMUM VALUE \\ OF CARRIER \\ CONCENTRATION\end{matrix} )}{( \begin{matrix}AVERAGE VALUE OF \\ CARRIER CONCENTRATION\end{matrix} )}$$

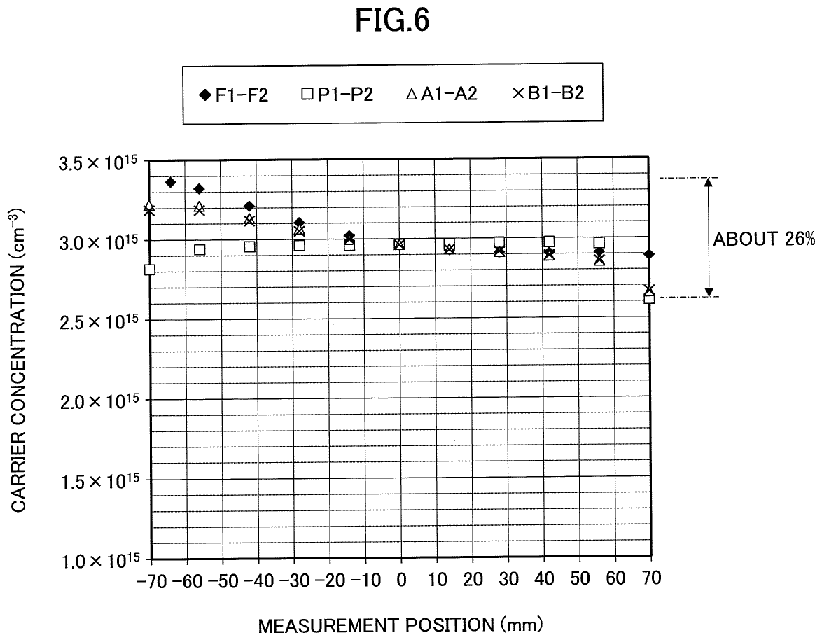

FIG. 6 shows a concentration distribution of a carrier concentration in the sample SE2 deposited by supplying ammonia gas at 0.065 sccm as the gas to dope the impurity element. As shown in FIG. 6, when a film is deposited by supplying ammonia gas, the carrier concentration in the silicon carbide epitaxial layer is likely to be high on the ori-fla (OF) side, and is likely to be relatively low on the opposite side to the ori-fla (OF). As a result, the width of the concentration distribution of the carrier concentration in the sample SE2 was about 26%.

In the meantime, when comparing FIG. 5 to FIG. 6, the concentration distribution of the carrier concentration when nitrogen gas is supplied and the concentration distribution of the carrier concentration when ammonia gas is supplied show different contributions from each other. Therefore, the inventors reached an idea that the concentration distribution of the carrier concentration can be made much more uniform by mixing nitrogen gas and ammonia gas and adjusting a mixing ratio between nitrogen gas and ammonia gas.

Hence, a sample SE3 is produced by supplying a mixed gas of nitrogen gas and ammonia gas as the gas to dope the impurity element, and the concentration distribution of the carrier concentration was examined using the same method as those of the sample SE1 and the sample SE2.

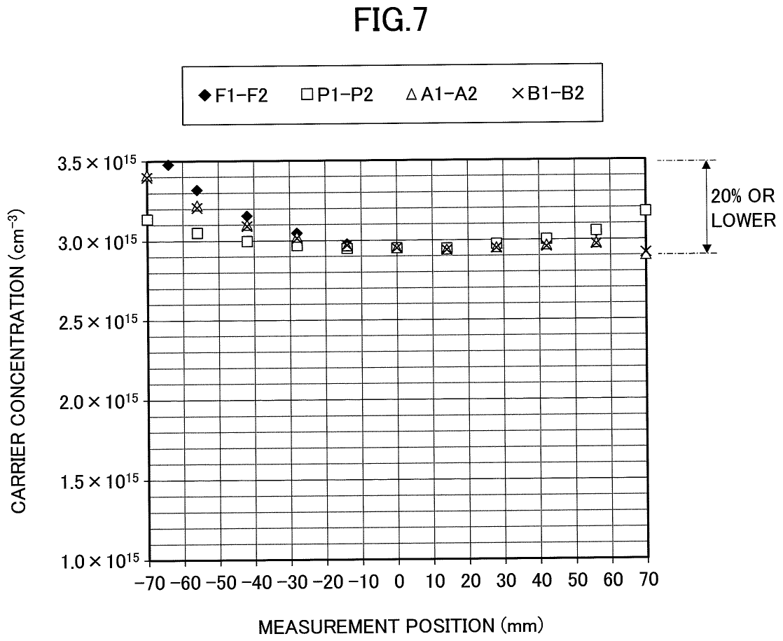

FIG. 7 shows a concentration distribution of a carrier concentration in the sample SE3 deposited by supplying nitrogen gas at 7.8 sccm and ammonia gas at 0.022 sccm. As illustrated in FIG. 7, when a film is deposited by supplying a mixed gas of nitrogen gas and ammonia gas, the concentration distribution of the carrier concentration in the silicon carbide layer became more unifoLm than those of the sample SE1 and the sample SE2, and a width of the concentration distribution in the sample SE3 was 20% or lower.

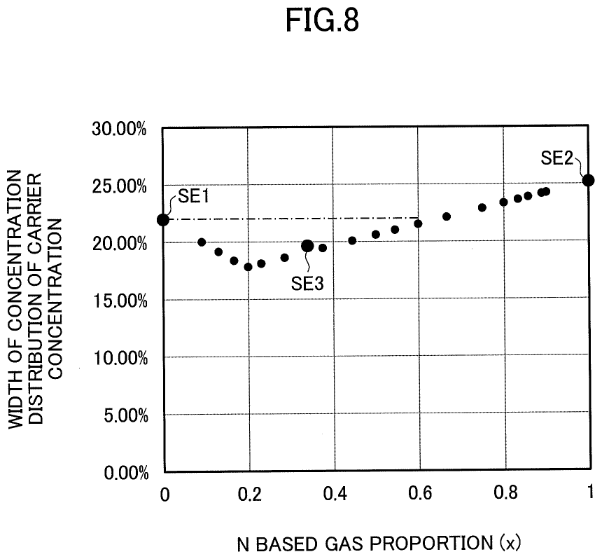

Based on the experimental results, a relationship between an N based gas proportion that is a supply ratio between nitrogen gas and ammonia gas, and a width of a concentration distribution of a carrier concentration was calculated. The result is shown in FIG. 8. Here, the N based gas proportion is a parameter of a supply ratio between nitrogen gas and ammonia gas, and when the N based gas ratio x is made x, nitrogen gas at 11*(1−X) sccm and ammonia gas at 0.065*X sccm are supplied. Hence, when the N based gas ratio x is made 0, only ammonia gas is supplied at 11 sccm, and only ammonia gas is supplied at 0.065 sccm when the N based gas ratio x is made 1.

From FIG. 8, a width of a concentration distribution of a carrier concentration can be reduced by supplying a mixed gas of nitrogen gas and ammonia gas while adjusting a mixing ration between nitrogen gas and ammonia gas. More specifically, when the N based gas ratio x is 0.2, the concentration distribution of the carrier concentration becomes the lowest, which becomes 18%. Furthermore, when the N based gas ratio x is 0.6 or lower, the width of the concentration distribution of the carrier concentration can be made smaller than when only nitrogen gas is supplied at 11 sccm. In addition, when the N based gas ratio x is not less than 0.09 and not more than 0.44, the width of the concentration distribution of the carrier concentration can be made 20% or lower.

When the N based gas proportion is 0.6, a flow rate of nitrogen gas is 4.4 sccm, and a flow rate of ammonia gas is 0.039 sccm, from which a ratio of the flow rate of ammonia gas to the flow rate of nitrogen gas is 0.0089. Hence, the ratio of the flow rate of ammonia gas to the flow rate of nitrogen gas ((the flow rate of ammonia gas)/(the flow rate of nitrogen gas)) is preferably beyond 0 and not less than 0.0089. In other words, ammonia gas is preferably supplied at a flow rate ratio of more than 0 and not less than 0.089 to nitrogen gas.

Moreover, when the N based gas proportion x is 0.09, the flow rate of nitrogen gas is 10.01 sccm; the flow rate of ammonia gas is 0.00585 sccm; and a ratio of the flow rate of ammonia gas to the flow rate of nitrogen gas becomes 0.00058. Furthermore, when the N based gas proportion x is 0.44; the flow rate of nitrogen gas is 6.16 sccm; the flow rate of ammonia gas is 0.0286 sccm; and the ratio of the flow rate of ammonia gas to the flow rate of nitrogen gas becomes 0.00464. Hence, the ratio of the flow rate of ammonia gas to the flow rate of nitrogen gas ((the flow rate of ammonia gas)/(the flow rate of nitrogen gas)) is preferably not less than 0.00058 and not more than 0.00464. In other words, ammonia gas is more preferably supplied at the flow rate ratio of not less than 0.00058 and not more than 0.00464 to nitrogen gas.

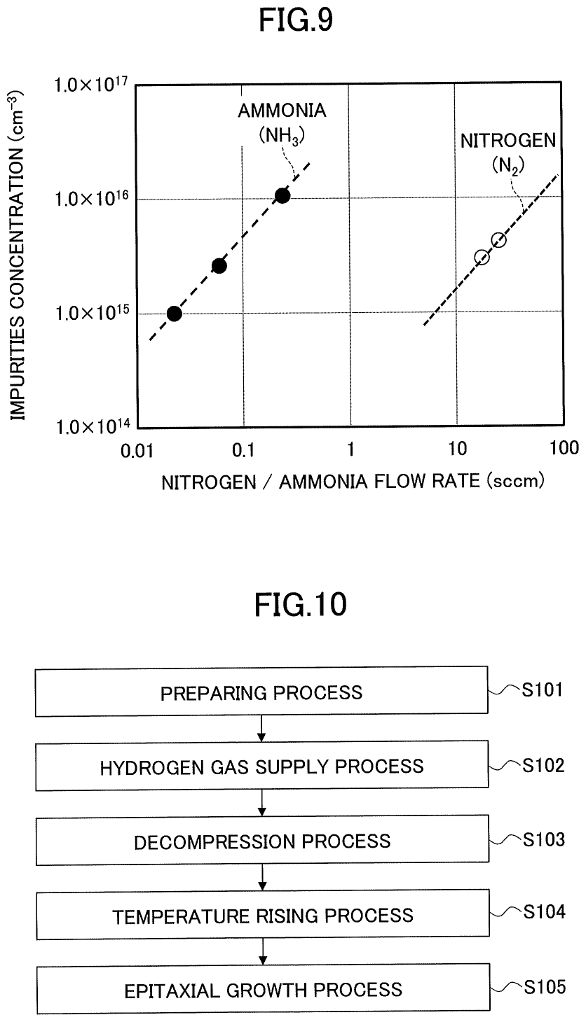

FIG. 9 shows a relationship between a flow rate of ammonia gas or nitrogen gas and an average value of a carrier concentration doped into a silicon carbide epitaxial layer. With respect to both ammonia gas and nitrogen gas, a flow rate of supplied gas and a doped carrier concentration are proportional to each other, and the carrier concentration doped to the silicon carbide epitaxial layer can be controlled by changing the flow rate of supplied gas. Hence, by changing the flow rate of nitrogen gas and the flow rate of ammonia gas while maintaining the ratio of ammonia gas to the flow rate of nitrogen gas at the above ratio, the doped carrier concentration can be changed while maintaining uniformity of the carrier concentration distribution.

Here, the distribution of the carrier concentration in the silicon carbide epitaxial layer deposited on the silicon carbide single crystal substrate 10 is likely to reduce its uniformity as the silicon carbide single crystal substrate 10 becomes larger. Hence, when the present embodiment is applied to the case where a diameter of the silicon carbide single crystal substrate 10 is not less than 100 mm, further not less than 150 mm, the present embodiment has a prominent effect.

[Method for Manufacturing Silicon Carbide Substrate]

Next, a method for manufacturing a silicon carbide epitaxial substrate in the present embodiment is described below.

FIG. 10 is a flowchart illustrating an outline of the method for manufacturing the silicon carbide epitaxial substrate in the present embodiment. As illustrated in FIG. 10, the method for manufacturing the silicon carbide epitaxial substrate of the present embodiment includes a preparing process (S101), a hydrogen gas supply process (S102), a decompression process (S103), a temperature rising process (S104), and an epitaxial growth process (S105). Each of the processes is described below.

In the preparing process (S101), a silicon carbide single crystal substrate 10 is prepared. The silicon carbide single crystal substrate 10 is produced by slicing an ingot that is made of, for example, a silicon carbide single crystal. For the slice, for example, a wire saw is used. A polytype of silicon carbide is preferably 4H. This is because the 4H polytype excels in electron mobility, breakdown electric field strength and the like more than the other polytypes. The diameter of the silicon carbide single crystal substrate 10 is preferably not less than 150 mm (for example, not less than 6 inches). As the diameter becomes larger, a cost of manufacturing the semiconductor device can be reduced advantageously.

The silicon carbide single crystal substrate 10 has a principal surface 10A on which the epitaxial layer 11 is to be grown later. The silicon carbide single crystal substrate 10 has an off angle θ that is beyond 0° and not more than 8°. In other words, the principal surface 10A is a surface inclined at the off angle θ that is beyond 0° and not more than 8° from a predetermined crystal plane. By introducing the off angle θ to the silicon carbide single crystal substrate 10, when the epitaxial layer 11 is grown by a CVD method, growth in a lateral direction from an atom step that has appeared on the principal surface 10A, what is called “step flow growth” is induced. Thus, a single crystal grows while inheriting a polytype of the silicon carbide single crystal substrate 10, and a mixture of a different type of polytype is reduced. Here, a predetermined crystal plane is preferably a (0001) plane or a (000-1) plane. That is, the predetermined crystal plane is preferably a {0001} plane. The off angle is provided in a direction of <11-20> direction. Subsequently, the preparing process (S101) and a process thereafter are performed in a film deposition apparatus.

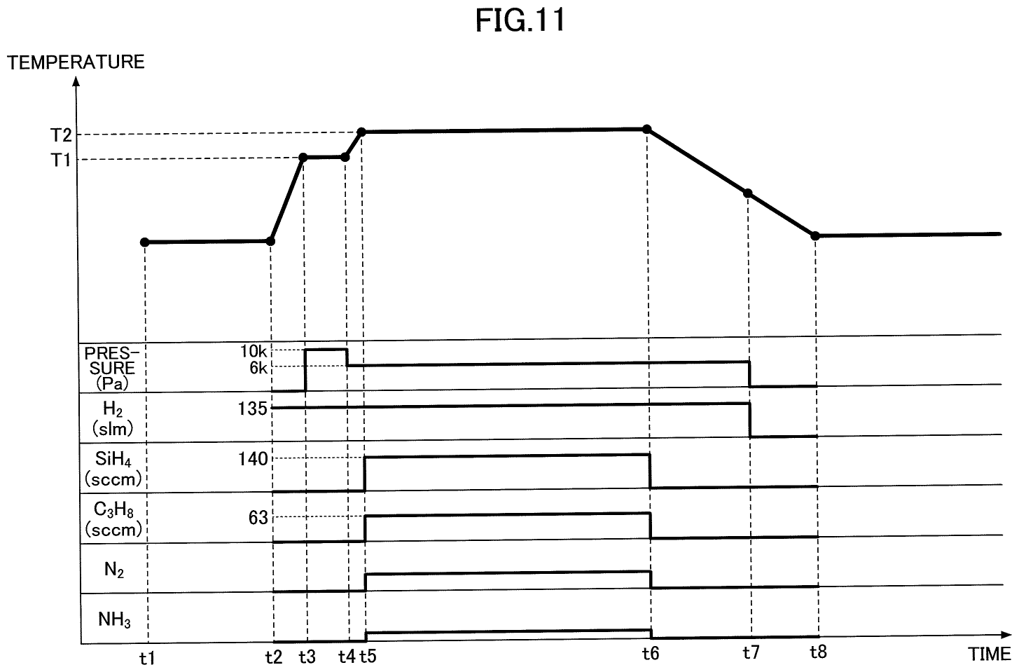

FIG. 11 is a timing chart illustrating control of a temperature and a gas flow rate in the chamber 1A performed in the film deposition apparatus. In the hydrogen gas supply process (S102), as illustrated in FIG. 2 and FIG. 3, a plurality of silicon carbide single crystal substrates 10 is loaded in the chamber 1A of the film deposition apparatus, and hydrogen gas (H₂) is supplied into the chamber 1A at a predetermined flow rate. More specifically, multiple, for example, three silicon carbide single crystal substrates 10 are placed on a substrate holder 7, and the substrate holder 7 on which the three silicon carbide single crystal substrates 10 are placed is installed on a rotary susceptor 8 in the chamber 1A. That is, a process of loading a plurality of silicon carbide single crystal substrates on a substrate holder is performed. Then, hydrogen (H₂) gas is supplied into the chamber 1A at a predetermined flow rate (for example, 135 slm in FIG. 11) from time t2. Graphite coated with SiC or a material made of SiC may be used as the rotary susceptor 8.

Next, in the decompression process (S103), the chamber is depressurized. In the decompression process (S103), the chamber 1A is depressurized till time t2 when the pressure in the chamber 1A reaches a target value. The target value of the pressure in the decompression process (S103) is, for example, in a range of about 1*10⁻³ Pa to about 1*10⁻⁶ Pa.

In the temperature rising process (S104), the temperature in the chamber 1A of the film deposition apparatus is heated to a first temperature T1 and is further heated to a second temperature T2. Here, hydrogen (H₂) gas is supplied into the chamber 1A at a flow rate of 135 ml for 10 minutes from time t3 when the temperature in the chamber 1A has reached the first temperature T1 to time t4 while maintaining the first temperature at T1. On this occasion, the pressure in the chamber 1A is adjusted to 10 kPa, for example. Subsequently, furthermore, the chamber 1A is heated so that the temperature in the chamber 1A of the film deposition apparatus 1 reaches the second temperature T2. Here, in the present embodiment, the first temperature T1 is, for example, 1620° C. Moreover, the rotation (revolution) of the substrate holder 7 may be performed after the plurality of silicon carbide single crystal substrates 10 is loaded in the chamber 1A of the film deposition apparatus 1 and before the epitaxial growth process (S105).

The second temperature T2 is preferably not less than 1500° C. and not more than 1750° C. When the second temperature T2 is below 1500° C., a single crystal is unlikely to grow uniformly in the subsequent epitaxial growth process (S105), and the growth rate may decrease. In addition, when the second temperature T2 exceeds 1750° C., etching action by hydrogen gas increases, which may cause a growth rate to decrease. The second temperature T2 is preferably not less than 1520° C. and not more than 1650° C. In the present embodiment, the temperature is 1640° C.

From time t5 when the temperature in the chamber 1A of the film deposition apparatus 1 reaches the second temperature T2, the epitaxial growth process (S105) is performed.

In the epitaxial growth process (S105), a hydrocarbon gas, silane (SiH₄) gas, nitrogen gas and ammonia gas are supplied onto the principal surfaces 10A of the silicon carbide single crystal substrates 10. A predetermined pressure in the chamber 1A in the epitaxial growth process (S105) is, for example, 6 kPa. Thus, the epitaxial layer 11 obtained by doping an impurity element that becomes an n-type onto the principal surfaces 10A of the silicon carbide single crystal substrates 10 by a CVD method. Here, the epitaxial growth process is preferably performed by rotating (revolution) the substrate holder 7. Thus, the epitaxial layer can be uniformly grown on the principal surfaces 10A of the plurality of silicon carbide single substrates 10 by uniformly supplying a gas to the plurality of silicon carbide single crystal substrates 10 while revolving (revolution) the plurality of silicon carbide single crystal substrates 10. However, rotating the substrate holder 7 is not required, but may be performed as necessary.

Methane (CH₄) gas, ethane (C₂H₆) gas, propane (C₃H₈) gas, butane (C₄H₁₀) gas, acetylene (C₂H₂) gas and the like can be used as the hydrocarbon gas. These hydrocarbon gases may be used alone, or may be used by mixing two or more types. That is, the hydrocarbon gas preferably contains one or more types selected from the groups consisting of methane gas, ethane gas, propane gas, butane gas and acetylene gas. In the present embodiment, for example, propane gas is supplied at 63 sccm as the hydrocarbon gas.

Moreover, although the flow rate of silane gas is not particularly limited, the flow rate of silane gas is preferably adjusted so that a ratio of the number of carbon (C) atoms contained in the hydrocarbon gas to the number of silicon (Si) atoms contained in the silane gas (C/Si) is not less than 0.5 and not more than 2.0. This aims at growing SiC having an appropriate stoichiometric proportion by epitaxial growth. In the present embodiment, for example, silane gas is supplied at 140 sccm. In this case, C/Si is 1.35.

In addition, a flow rate of nitrogen gas supplied in the epitaxial growth process (S105) is not less than 4.4 sccm and below 11 sccm, and is preferably not less than 6.16 sccm and not more than 10.01 sccm. Furthermore, a flow rate of supplied ammonia is beyond 0 and not more than 0.039 sccm, and is preferably not less than 0.0585 sccm and not more than 0.0286 sccm. In the present embodiment, the flow rate of supplied nitrogen is 7.8 sccm, and the flow rate of ammonia gas is 0.022 sccm. The epitaxial growth process (S105) is performed till time t6 while being in accordance with the thickness of the targeted epitaxial layer 11. In the present embodiment, the epitaxial growth process (S105) is performed for about 150 minutes, thereby forming the silicon carbide epitaxial layer 11 having a thickness of 30 μm and a carrier concentration of 3*10¹⁵ cm⁻³.

After completing the epitaxial growth process (S105), the silicon carbide epitaxial substrate on which the silicon carbide epitaxial layer is deposited is cooled. The cooling is performed by stopping the heating by the induction heating coil 3 of the film deposition apparatus 1, and hydrogen gas is supplied till time t7 when the temperature in the chamber 1A reaches 600° C., and the supply of hydrogen gas is stopped at and after time t7. Subsequently, after the chamber 1A is cooled till time t8 when the formed silicon carbide epitaxial substrate can be taken out, the chamber 1A is open to the atmosphere so that the pressure in the chamber 1A returns to atmosphere pressure, and the silicon carbide epitaxial substrate 100 is taken out of the chamber 1A.

The silicon carbide epitaxial substrate 10 in the present embodiment can be manufactured by the following processes.

### Second Embodiment

Next, a second embodiment is described below. The present embodiment causes the silicon carbide single crystal substrate 10 to rotate and revolve while supplying a gas containing ammonia gas in depositing a silicon carbide epitaxial layer 11 on the silicon carbide single crystal substrate 10. That is, the present embodiment is a method for manufacturing a silicon carbide epitaxial substrate by rotating and revolving a plurality of silicon carbide single crystal substrates 10 while supplying ammonia gas or a mixed gas of nitrogen gas and ammonia gas, and depositing the silicon carbide epitaxial layer 11 on the plurality of silicon carbide single crystal substrates 10. Here, in the present embodiment, in the revolution, the substrate holder 7 is rotated by rotating the rotary susceptor 8 about the axis extending perpendicular to the principal surface 10A of the silicon carbide single crystal substrate 10. Moreover, in the rotation, the substrate holder 7 is rotated by rotating the rotary susceptor 8 about the axis extending perpendicular to the principal surface 10A of the silicon carbide single crystal substrate 10 at the center of the silicon carbide single crystal substrate 10.

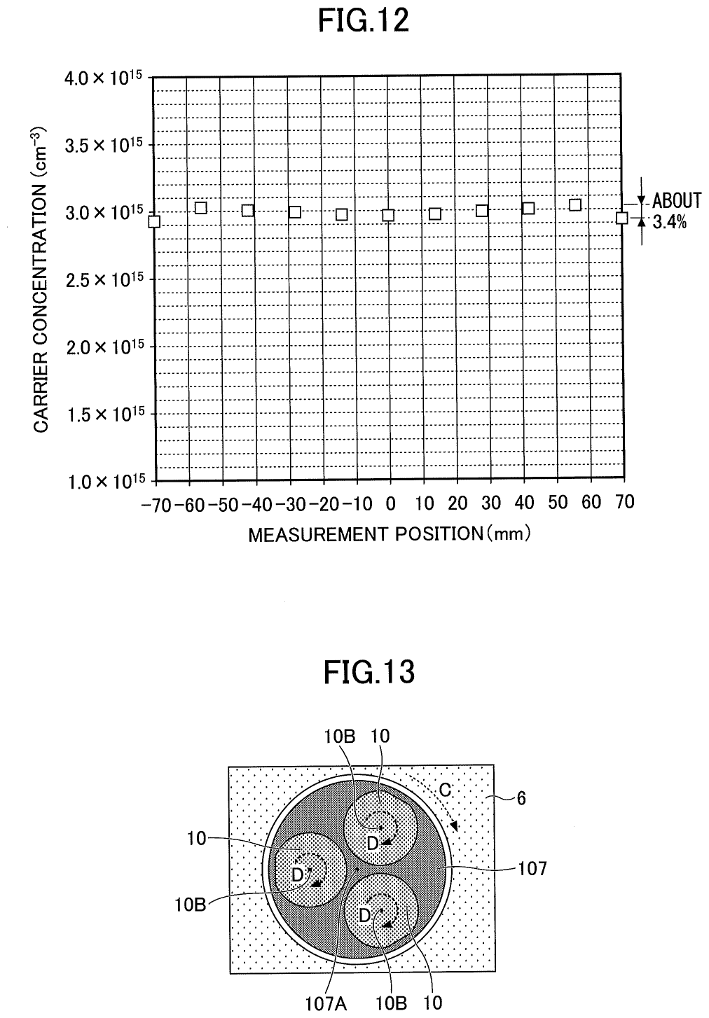

Based on the results shown in FIG. 6 and FIG. 7, a width of a concentration distribution is considered to decrease by further rotating (rotation) the silicon carbide single crystal substrates 10 in addition to the revolution. In other words, the width of the concentration distribution is inferred to further decrease by rotating and revolving the silicon carbide single crystal substrates 10 while supplying ammonia gas or a mixed gas of ammonia gas and nitrogen gas. FIG. 12 is a diagram calculating a concentration distribution of a carrier concentration in a silicon carbide epitaxial layer when being rotated and revolved based on the results shown in FIG. 7. The width of the concentration distribution of the carrier concentration in this case is about 4.4%.

More specifically, as shown in FIG. 5, when nitrogen gas is supplied, because the central location of the concentration distribution of the carrier concentration is low and the peripheral locations are high, the tendency does not change even if the silicon carbide single crystal substrates 10 are rotated and revolved. Hence, when nitrogen gas is supplied, the width of the concentration distribution of the carrier concentration does not decrease much. In contrast, as shown in FIG. 6, when ammonia gas is supplied, the central location of the concentration distribution of the carrier concentration is approximately uniform, and a high location and a low location are present at the peripheral locations. Hence, by rotating and revolving the silicon carbide single crystal substrates 10, the location having the high carrier concentration and the location having the low carrier concentration are considered to be likely to balance, and to significantly decrease the width of the concentration distribution of the carrier concentration.

This tendency applies similarly to the case of supplying the mixed gas of nitrogen gas and ammonia gas shown in FIG. 7, the uniformity is considered to be further improved by adjusting a mixing ratio between nitrogen gas and ammonia gas. More specifically, from the first embodiment, a mixing ratio of a flow rate of nitrogen gas to a flow rate of ammonia gas ((flow rate of ammonia gas)/(flow rate of nitrogen gas)) is preferably beyond 0 and not more than 0.0089, and is further preferably not less than 0.00058 and not more than 0.00464.

FIG. 13 is a top view of the inside of a chamber of a film deposition apparatus used for manufacturing a silicon carbide epitaxial substrate in the present embodiment. In the method for manufacturing the silicon carbide epitaxial substrate in the present embodiment, a substrate holder 107 that can rotate placed silicon carbide single crystal substrates 10 is used. The substrate holder 107 is installed in the chamber 1A instead of the substrate holder 7 illustrated in FIG. 2. In the present embodiment, by rotating the rotary susceptor 8, the substrate holder 107 rotates in a direction indicated by a broken arrow C about a rotational axis 107A of the substrate holder 107, and each of the silicon carbide single crystal substrates 10 is rotated about a center 10B of each of the silicon carbide single crystal substrates 10 in a direction shown by broken arrows D. In the present embodiment, the silicon carbide epitaxial layer 11 is deposited by supplying ammonia gas or a mixed gas of nitrogen gas and ammonia gas while rotating each of the silicon carbide single crystal substrates 10 and revolving the silicon carbide single crystal substrates 10 in this manner. The rotation (revolution) of the rotary susceptor 8 to rotate the substrate holder 7 and the rotation (rotation) of the silicon carbide single crystal substrate 10 are performed by, for example, a gas flow method. The rotational speed of the rotation in this case may be about 50 RPM or may be lower than 50 RPM.

The description other than the above is the same as that of the first embodiment.

Although the embodiments have been described hereinabove, the disclosure is not limited to specific embodiments, a variety of modifications and variations may be made without departing from the scope of the present disclosure.

With respect to the above embodiment, the following numbered clauses are further disclosed.

(Clause 1)

A method for manufacturing a silicon carbide epitaxial substrate, including steps of:

preparing a plurality of silicon carbide single crystal substrates; and

depositing a silicon carbide epitaxial layer on the plurality of silicon carbide single crystal substrates,

wherein the step of depositing the silicon carbide epitaxial layer is a step of depositing the silicon carbide epitaxial layer on the plurality of silicon carbide single crystal substrates at the same time by loading the plurality of silicon carbide single crystal substrates on a substrate holder, and rotating the substrate holder about an axis perpendicular to a principal surface of the silicon carbide single crystal substrates,

wherein the silicon carbide epitaxial layer is formed by supplying a gas containing carbon, a gas containing silicon, nitrogen gas and ammonia gas, and

wherein a flow rate of the ammonia gas to a flow rate of the nitrogen gas is not more than 0.0089.

(Clause 2)

A method for manufacturing a silicon carbide epitaxial substrate, including steps of:

preparing a plurality of silicon carbide single crystal substrates; and

depositing a silicon carbide epitaxial layer on the plurality of silicon carbide single crystal substrates,

wherein the step of depositing the silicon carbide epitaxial layer is a step of depositing the silicon carbide epitaxial layer on the plurality of silicon carbide single crystal substrates at the same time by loading a plurality of silicon carbide single crystal substrates on a substrate holder, and rotating the substrate holder about an axis perpendicular to a principal surface of the silicon carbide single crystal substrates and rotating each of the silicon carbide single crystal substrates about an axis perpendicular to a principal surface of each of the silicon carbide single crystal substrates; and

supplying a gas containing carbon, a gas containing silicon, and ammonia gas.

(Clause 3)

The method for manufacturing the silicon carbide epitaxial substrate as described in clause 2,

wherein nitrogen gas is also supplied in the step of depositing the silicon carbide epitaxial layer, and

wherein a flow rate of the ammonia gas to the flow rate of the nitrogen gas is not more than 0.0089.

A method for manufacturing a silicon carbide epitaxial substrate includes steps of:

preparing a silicon carbide single crystal substrate; and

depositing a silicon carbide epitaxial layer on the silicon carbide single crystal substrate,

wherein the silicon carbide epitaxial layer is formed by supplying a gas containing carbon, a gas containing silicon, nitrogen gas and ammonia gas, and

wherein a flow rate of the ammonia gas to a flow rate of the nitrogen gas is not more than 0.0089.

### DESCRIPTION OF THE REFERENCE NUMERALS

1 film deposition apparatus
1A chamber
3 induction heating coil
4 quartz tube
5 heat insulator
6 heating element
6A curved part
6B flat part
7 substrate holder
7A rotational axis
10 single crystal substrate
10A principal surface
10B center
11 epitaxial layer
11A surface
100 silicon carbide epitaxial substrate
107 substrate holder
107A rotational axis

1. A method for manufacturing a silicon carbide epitaxial substrate, comprising steps of:
loading a plurality of silicon carbide single crystal substrates on a substrate holder; and
depositing a silicon carbide epitaxial layer on the plurality of silicon carbide single crystal substrates at the same time by rotating the substrate holder about an axis perpendicular to a principal surface of the silicon carbide single crystal substrates while supplying a gas containing carbon, a gas containing silicon, nitrogen gas and ammonia gas,
wherein a flow rate of the ammonia gas to a flow rate of the nitrogen gas is not more than 0.0089.

2. A method for manufacturing a silicon carbide epitaxial substrate, comprising steps of:
loading a plurality of silicon carbide single crystal substrates on a substrate holder; and
depositing a silicon carbide epitaxial layer on the plurality of silicon carbide single crystal substrates at the same time by rotating the substrate holder about an axis perpendicular to a principal surface of the silicon carbide single crystal substrates and rotating each of the silicon carbide single crystal substrates about an axis perpendicular to a principal surface of each of the silicon carbide single crystal substrates while supplying a gas containing carbon, a gas containing silicon, and ammonia gas.

3. The method for manufacturing the silicon carbide epitaxial substrate as claimed in claim 2,
wherein nitrogen gas is also supplied in the step of depositing the silicon carbide epitaxial layer, and
wherein a flow rate of the ammonia gas to the flow rate of the nitrogen gas is not more than 0.0089.

4. A method for manufacturing a silicon carbide epitaxial substrate, comprising a step of:
depositing a silicon carbide epitaxial layer on a silicon carbide single crystal substrate by supplying a gas containing carbon, a gas containing silicon, nitrogen gas and ammonia gas,
wherein a flow rate of the ammonia gas to a flow rate of the nitrogen gas is not more than 0.0089.

5. The method for manufacturing the silicon carbide epitaxial substrate as claimed in claim 1,
wherein the gas containing the carbon is propane, and
wherein the gas containing the silicon is silane.

6. The method for manufacturing the silicon carbide epitaxial substrate as claimed in claim 1,
wherein a diameter of the silicon carbide single crystal substrate is not less than 100 mm.

7. The method for manufacturing the silicon carbide epitaxial substrate as claimed in claim 1,
wherein the silicon carbide epitaxial layer is formed by film deposition by a CVD method.

8. The method for manufacturing the silicon carbide epitaxial substrate as claimed in claim 2,
wherein the gas containing the carbon is propane, and
wherein the gas containing the silicon is silane.

9. The method for manufacturing the silicon carbide epitaxial substrate as claimed in claim 2,
wherein a diameter of the silicon carbide single crystal substrate is not less than 100 mm.

10. The method for manufacturing the silicon carbide epitaxial substrate as claimed in claim 2,
wherein the silicon carbide epitaxial layer is formed by film deposition by a CVD method.

11. The method for manufacturing the silicon carbide epitaxial substrate as claimed in claim 4,
wherein the gas containing the carbon is propane, and
wherein the gas containing the silicon is silane.

12. The method for manufacturing the silicon carbide epitaxial substrate as claimed in claim 4,
wherein a diameter of the silicon carbide single crystal substrate is not less than 100 mm.

13. The method for manufacturing the silicon carbide epitaxial substrate as claimed in claim 4,
wherein the silicon carbide epitaxial layer is formed by film deposition by a CVD method.
